(19) United States
(12) Patent Application Publication
(10) Pub. No.: US 2011/0114374 A1
(43) Pub. Date: May 19, 2011

(54) ELECTRODE PLATE WITH CONDUCTIVE COAT AND PANEL-TYPE INPUT DEVICE

(75) Inventors: Hideki IWATA, Shinagawa (JP); Michiko ENDO, Shinagawa (JP); Yuriko SEGAWA, Shinagawa (JP)

(73) Assignee: FUJITSU COMPONENT LIMITED, Tokyo (JP)

(21) Appl. No.: 12/948,168

(22) Filed: Nov. 17, 2010

(30) Foreign Application Priority Data
Nov. 17, 2009 (JP) 2009-261992

(51) Int. Cl. H05K 1/09

(52) U.S. Cl. 174/257

(57) ABSTRACT

An electrode plate with a conductive coat, which includes a substrate and a conductive coat provided on a surface of the substrate. The conductive coat includes a first conductive member laminated on the surface of the substrate, the first conductive member being formed from a conducting polymer; and a second conductive member placed on a surface of the first conductive member in a distributed manner, the second conductive member being formed from an inorganic conductive material. An electric conductivity of the inorganic conductive material forming the second conductive member is higher than an electric conductivity of the conducting polymer forming the first conductive member.

### BACKGROUND OF THE INVENTION

1. Field of the Invention

The present invention relates to an electrode plate with an electrically-conductive coat provided along one side of the electrode plate. The present invention also relates to a panel-type input device including an electrode plate with an electrically-conductive coat.

2. Description of the Related Art

A panel-type input device has been known as an input device (or a coordinate detecting device) of an electronic apparatus including a display unit, such as a personal computer, a personal digital assistant (PDA), an automatic teller machine (ATM), etc., which is operated to indicate two-dimensional coordinate data in the display unit by an operator touching a desired point on a panel surface with a finger or a pen. In particular, a panel-type input device having a transparent structure, which can be mounted on a screen of a display unit, such as a liquid crystal display (LCD), a plasma display panel (PDP), a cathode ray tube (CRT), etc., has been widely used as a so-called touch panel, and in recent years, has been installed in a portable terminal unit having cellular phone functions.

A resistive-type touch panel, as one example of a panel-type input device, includes a pair of transparent electrode plates, each having a transparent insulating substrate and a transparent electrically-conductive coat or coating provided on a surface of the substrate, and has a configuration wherein the electrode plates are assembled with each other in a relative arrangement that the conductive coats are opposed to and spaced from each other while permitting an electrically-conductive contact therebetween. As input coordinate detection systems provided for the resistive-type touch panel, an analog system in which the conductive coat of each electrode plate is configured to be uniformly formed over the generally entire surface of the substrate, and a digital system in which the conductive coat of each electrode plate is configured to be divided into a plurality of strip-shaped portions on the surface of the substrate, have been known.

In a conventional panel-type input device as described above, the conductive coat is typically formed on the surface of the substrate by a coat-forming technology, such as vacuum deposition, sputtering, etc., using a metal oxide (i.e., an inorganic conductive material), such as an indium tin oxide (ITO). Further, in recent years, a panel-type input device provided with an electrically conductive coat or coating formed from an electrically conductive polymer (hereinafter referred to as a conducting polymer) has been proposed. In comparison with an ITO coat, the conductive coat formed from the conducting polymer has advantages in that the conducting polymer is excellent in impact resistance, writing durability, etc., and can be formed by a simple process such as coating or printing. On the other hand, the conductive coat formed from the conducting polymer typically has a lower electric conductivity than the ITO coat.

For example, Japanese Unexamined Patent Publication (Kokai) No. 2003-196029 (JP2003-196029A) describes a touch panel in which a first transparent substrate and a second transparent substrate, with a transparent conductive coat or coating provided on the surface of each substrate, are disposed so that the transparent conductive coats are opposed to and spaced with a certain distance from each other. JP2003-196029A describes “a material of the transparent conductive coats is not particularly limited, but can be appropriately selected from publicly known conductive materials, such as metallic oxides, oxide semiconductors, conducting polymers, etc.”

Japanese Unexamined Patent Publication (Kokai) No. 2005-019056 (JP2005-019056A) describes a transparent electrode (or a transparent conductive base material) adapted to be used in an inorganic EL display, a touch panel, a smart window, an electronic paper, etc., which is explained as “a complex transparent conductive base material formed by mutually laminating at least (A) a base material formed of a polymer film or a polymer sheet, (B) a metallic transparent conductive thin film and (C) an conductive organic substance.” JP2005-019056A describes “the laminated structure may be suitably selected depending on applications from the stack of (A) a base material formed of a polymer film or a polymer sheet/(B) a metallic transparent conductive thin film/(C) a conductive organic substance, as illustrated in FIG. 1; the stack of (A) a base material formed of a polymer film or a polymer sheet/(C) a conductive organic substance/(B) a metallic transparent conductive thin film, as illustrated in FIG. 2; and the stack of (A) a base material formed of a polymer film or a polymer sheet/(C) a conductive organic substance/(B) a metallic transparent conductive thin film/(C) a conductive organic substance, as illustrated in FIG. 3.”

### SUMMARY OF THE INVENTION

In a resistive-type, panel-type input device including an electrode plate with a conductive coat, opposing conductive coats frequently contact with or detach from each other, and therefore it is desired to effectively improve the durability of the conductive coat.

According to one aspect of the present invention, an electrode plate with a conductive coat is provided, which comprises a substrate and a conductive coat or coating provided on a surface of the substrate, the conductive coat comprising a first conductive member laminated on the surface of the substrate, the first conductive member being formed from a conducting polymer; and a second conductive member placed on a surface of the first conductive member in a distributed manner, the second conductive member being formed from an inorganic conductive material, wherein an electric conductivity of the inorganic conductive material forming the second conductive member is higher than an electric conductivity of the conducting polymer forming the first conductive member.

According to the above configuration, the mechanical strength and electrical durability of the conductive coat is improved due to the cooperation of the first conductive member and the second conductive member. Further, since the second conductive member is formed on the first conductive member in a distributed manner, it is possible to prevent degradation in transmittance of the electrode plate, and there is an advantage in more choices in materials of the second conductive member. Thus, the electrode plate according to the present invention can be safely and preferably used as an electrode plate of a resistive-type, panel-type input device in which opposing conductive coats frequently contact with or detach from each other.

In the above electrode plate, the second conductive member may include a plurality of dot-like elements separated from each other, or alternatively, may include a plurality of linear elements joined to each other in a net-like manner.

According to another aspect of the present invention, a panel-type input device is provided, which comprises a pair of electrode plates, each electrode plate comprising a substrate and a conductive coat or coating provided on a surface of the substrate, the pair of electrode plates being assembled with each other in a relative arrangement such that conductive coats of the electrode plates are opposed to and spaced from each other while permitting a conductive contact between the conductive coats, wherein at least one of the pair of electrode plates comprises the electrode plate as described above.

According to the above configuration, since the electrode plate with the conductive coat superior in the mechanical strength and electrical durability is used, it is possible to prevent malfunctions such that errors occur in a coordinate detection position and a touch input cannot be detected, due to a repeated touch input operation.

### BRIEF DESCRIPTION OF THE DRAWINGS

The above and other objects, features and advantages of the present invention will become more apparent from the following description of the preferred embodiments in connection with the accompanying drawings, wherein:

FIG. 1 is a perspective view depicting an electrode plate with a conductive coat, according to a first embodiment of the present invention;

FIG. 2 is a sectional view depicting the electrode plate of FIG. 1, taken along a line II-II in FIG. 1;

FIG. 3 is an exploded perspective view depicting a panel-type input device according to an embodiment of the present invention;

FIG. 4 is a sectional view depicting the panel-type input device of FIG. 3 in an assembled state;

FIG. 5 is a sectional view depicting a modification of the panel-type input device;

FIG. 6 is a perspective view depicting an electrode plate with a conductive coat, according to a second embodiment of the present invention; and

FIG. 7 is a sectional view depicting the electrode plate of FIG. 6, taken along a line VII-VII in FIG. 6.

### DESCRIPTION OF THE PREFERRED EMBODIMENT

The embodiments of the present invention are described below, in detail, with reference to the accompanying drawings. In the drawings, the same or similar components are denoted by common reference numerals.

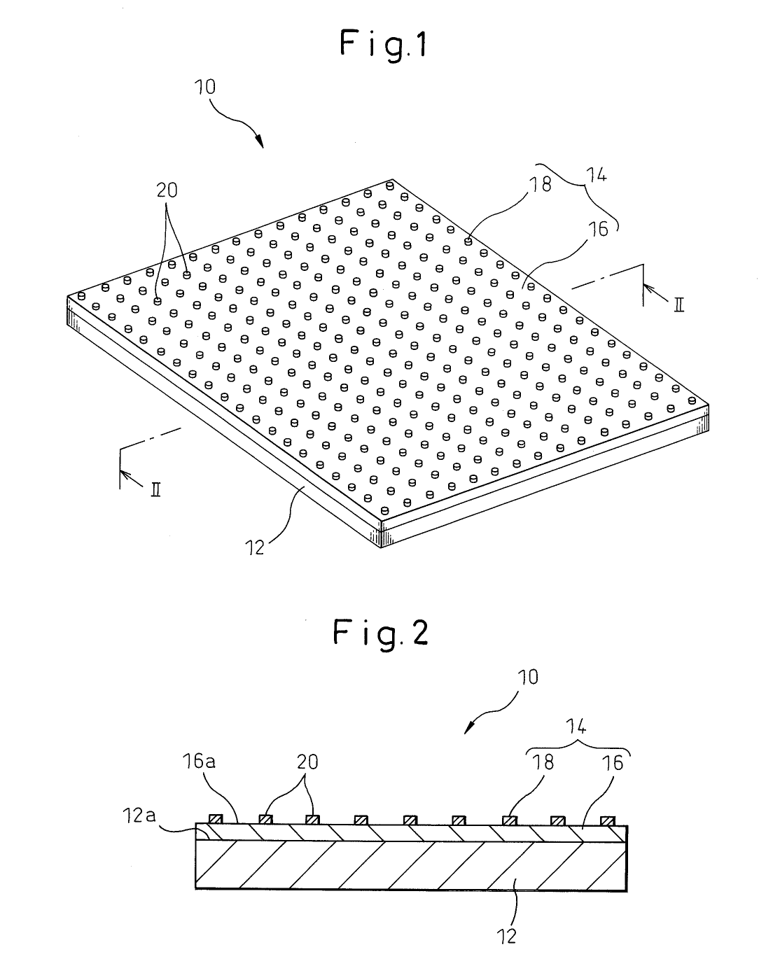

Referring to the drawings, FIGS. 1 and 2 illustrate an electrode plate 10 with a conductive coat, according to a first embodiment of the present invention. The electrode plate 10 includes an electrically insulating substrate 12, and an electrically conductive coat or coating 14 provided on a surface 12a of the substrate 12. The substrate 12 may be formed from an inflexible flat plate, such as a glass plate, a resin plate, etc., or a flexible sheet, such as a resinous film. Resinous materials suitable for the substrate 12 may include polycarbonate, acryl, polyethylene terephthalate (PET), etc. When the electrode plate 10 is used to constitute a resistive-type touch panel, the substrate 12 is formed from a transparent material. The shape of the substrate 12 is not particularly limited, but may be, for example, a rectangular profile as illustrated, which is typically used in the resistive-type touch panel.

The conductive coat 14 includes a first conductive member 16 laminated on the surface 12a of the substrate 12, and a second conductive member 18 placed on a surface 16a of the first conductive member 16 in a distributed manner. The first conductive member 16 is formed by using an electrically conductive polymer (i.e., a conducting polymer) so as to entirely cover the surface 12a of the substrate 12 as a coating. The second conductive member 18 is formed by using an inorganic conductive material so as to be appropriately distributed across the entire surface 16a of the first conductive member 16 as a member separated from the first conductive member 16. In the illustrated embodiment, the second conductive member 18 includes a plurality of dot-like elements 20 separated from each other. The dot-like elements 20 are arranged across the entire surface 16a of the first conductive member 16 in a uniformly dispersed manner. When the electrode plate 10 is used to constitute a resistive-type touch panel, the first conductive member 16 is formed from a transparent material.

One example of the conducting polymer that can be preferably used for the first conductive member 16 is, e.g., a polythiophene-based conducting polymer. In particular, when the electrode plate 10 is used for a touch panel having a transparent structure, the polythiophene-based polymer is preferred in excellent transparency. Other conducting polymers that can be used for the electrode plate 10 may include polyaniline, polypyrrole, polyethylenedioxythiophene, etc. Surface resistivity of the first conductive member 16 made of the conducting polymer (pursuant to, e.g., JIS K6911) is not particularly limited, but, e.g., is 4800Ω/□ (ohm/square) or less, preferably 2800Ω/□ or less, and more preferably 1480Ω/□ or less. If the surface resistivity exceeds 4800Ω/□, input responsiveness may be impaired.

Thickness of the first conductive member 16 formed from the conducting polymer is not particularly limited, but preferably is in the range of 0.01 μm to 10 μm, and more preferably is in the range of 0.1 μm to 1 μm. If the thickness is less than 0.01 μm, electrical resistance of the first conductive member 16 may become unstable. On the other hand, if the thickness is more than 10 μm, adhesiveness between the first conductive member 16 and the substrate 12 may be degraded. In the illustrated embodiment, the first conductive member 16 has a uniform thickness in its entirety, but may have a nonuniform thickness. Process for forming the first conductive member 16 on the surface 12a of the substrate 12 is not particularly limited, but a coating process such as spin coating, roller coating, bar coating, dip coating, gravure coating, curtain coating, die coating, spray coating, doctor coating, kneader coating, etc., or a printing process such as screen printing, spray printing, inkjet printing, relief printing, intaglio printing, planographic printing, etc., may be adopted.

An inorganic conductive material that can be preferably used for the second conductive member 18 is not particularly limited, but may include metallic oxides such as ITO or ZnO (zinc oxide), metals such as gold, alloys, carbon, carbon nanotube, etc. In the electrode plate 10, the inorganic conductive material forming the second conductive member 18 is selected so as to have an electric conductivity higher than the electric conductivity of the conducting polymer forming the first conductive member 16. The electric conductivity of the second conductive member 18 is in a range of, e.g., 1,000 S/cm to 10,000 S/cm.

Thickness of the second conductive member 18 formed from the inorganic conductive material is not particularly limited, but preferably is in the range of 0.01 μm to 10 μm, and more preferably is in the range of 0.1 μm to 1 μm. If the thickness is less than 0.01 μm, electrical resistance of the second conductive member 18 may become unstable. On the other hand, if the thickness is more than 10 μm, adhesiveness between the second conductive member 18 and the first conductive member 16 may be degraded. In the illustrated embodiment, all dot-like elements 20 of the second conductive member 18 have an identical thickness, but the thickness of some dot-like elements 20 may be different from the thickness of the other dot-like elements 20.

Each of the dot-like elements 20 constituting the second conductive member 18 has a cylindrical shape with a diameter in the range of, e.g., about 5 μm to 100 μm. The dot-like elements 20 are arranged on the surface 16a of the first conductive member 16 with a pitch in the range of, e.g., about 50 μm to 500 μm. In the illustrated embodiment, the dot-like elements 20 constituting the second conductive member 18 are formed in an entirely regular arrangement, but may be formed in an entirely or partially irregular arrangement.

Process for forming the second conductive member 18 made of the inorganic conductive material is not particularly limited, but may adopt, e.g., a combination of a coat-forming technology including physical vapor deposition (PVD) such as vacuum deposition, sputtering, etc., and a wet coating, etc., and a material removing technology including physical etching such as laser trimming, etc., and a wet etching, etc. In this configuration, a thin-film coating made of the inorganic conductive material is uniformly formed on the entire surface 16a of the first conductive member 16 by the coat forming technology, and thereafter the desired portions of the thin-film coating is locally removed by the material removing technology. Alternatively, the second conductive member 18 may be formed by printing a fluid dispersion in liquid or paste form, which is formed by mixing the inorganic conductive material in a powder and granular form with a vehicle, on the surface 16a of the first conductive member 16 in a desired pattern by screen printing or inkjet printing, and solidifying the printed fluid dispersion by drying or ultraviolet irradiation. Through the above processes, it is possible to place the second conductive member 18 in a fixed manner on the surface 16a of the first conductive member 16 in an appropriately distributed arrangement.

The electrode plate 10 configured as described above has an advantage such that the mechanical strength of the conductive coat 14 is improved due to the cooperation of the first conductive member 16 and the second conductive member 18. In particular, the upper second conductive member 18 formed from the relatively fragile inorganic conductive material is supported by the lower first conductive member 16 formed from the relatively flexible or soft conducting polymer, and therefore, when the electrode plate 10 is used as, e.g., an electrode plate of a resistive-type, panel-type input device, it is possible to prevent the second conductive member 18 from being mechanically damaged due to repeated touch inputs. Further, as described later, it is possible to prevent the conductive coat 14 from being electrically damaged and to prevent the electric resistance thereof from consequently increasing, due to the repeated touch inputs.

Further, in the electrode plate 10, an entire electric conductivity of the conductive coat 14 is determined depending not on an electric conductivity of the second conductive member 18 distributed on the first conductive member 16 but on an electric conductivity of the first conductive member 16 formed over the entire surface of the substrate 12. Consequently, even if the upper second conductive member 18 is mechanically damaged, the entire electric conductivity of the conductive coat 14 is substantially not affected. As a result, the conductive coat 14 of the electrode plate 10 obtains excellent electric and mechanical durability, and it is thus possible to safely use the electrode plate 10 as an electrode plate of a resistive-type, panel-type input device in which opposing conductive coats frequently contact with or detach from each other.

Still further, in the electrode plate 10, the second conductive member 18 is formed on the first conductive member 16 in a distributed manner, and therefore, when the electrode plate 10 is used as, e.g., a transparent electrode plate of a resistive-type touch panel, it is possible to reduce an influence on a screen visibility (i.e., to prevent degradation in transmittance) of a display unit through the electrode plate 10. Moreover, when the shapes and dimensions of the dot-like elements 20 constituting the second conductive member 18, as well as an arrangement of the dot-like elements 20 on the first conductive member 16, are appropriately selected, it is possible to use the electrode plate 10 including the second conductive member 18 formed from an opaque inorganic conductive material such as carbon, in the resistive-type touch panel. As a result, there is an advantage in more choices in materials.

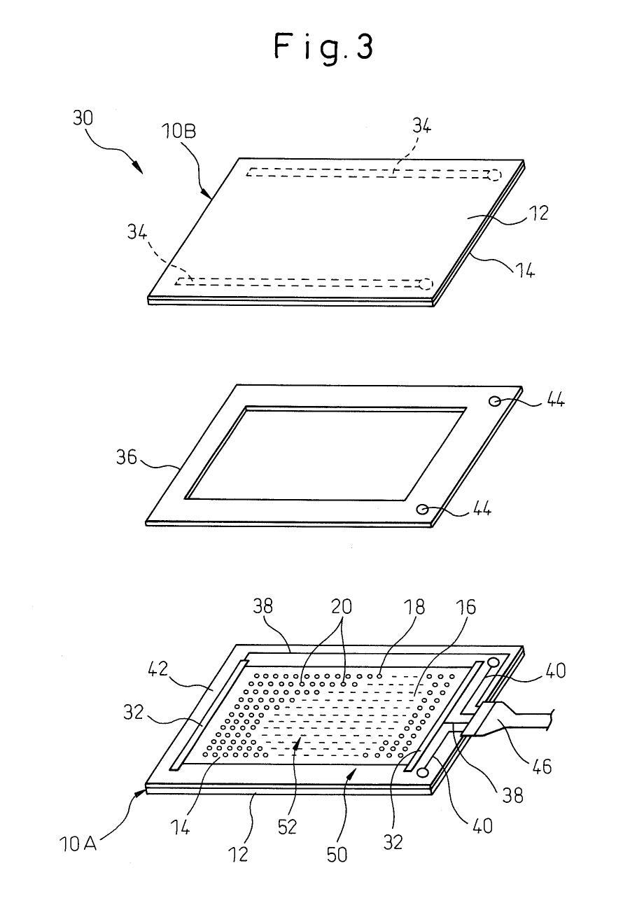

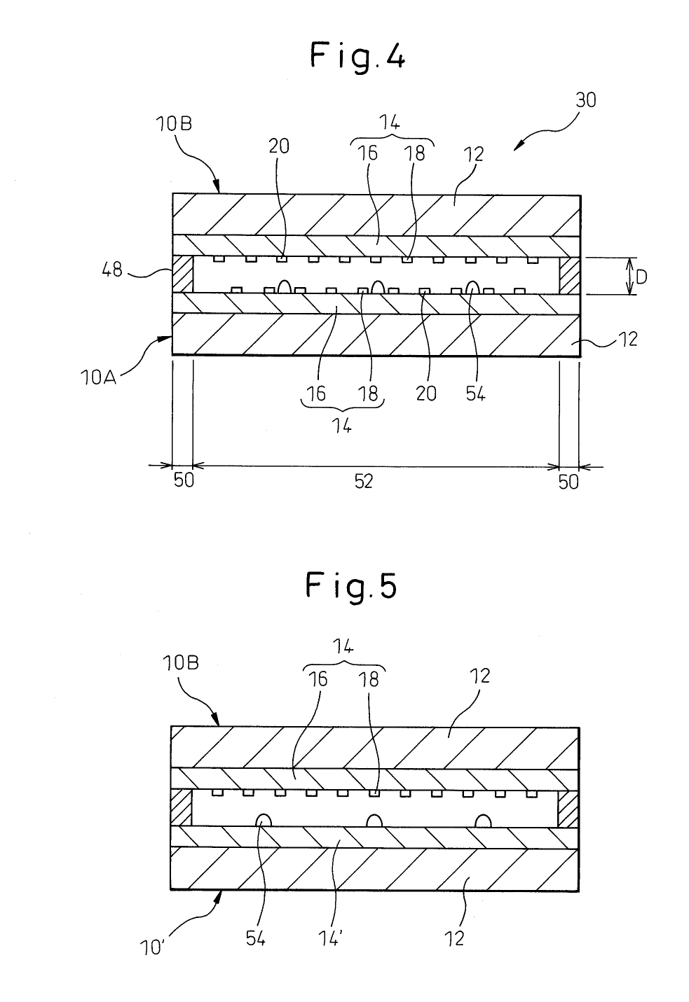

FIGS. 3 and 4 illustrate a panel-type input device 30 according to an embodiment of the present invention, which includes a pair of electrode plates 10A and 10B, each electrode plate 10A, 10B having a configuration of the electrode plate 10 described above. The panel-type input device 30 has a configuration applicable to an analog-system based resistive-type touch panel. The panel-type input device 30 includes a first electrode plate 10A including a substrate 12 and a conductive coat or coating 14, and a second electrode plate 10B including a substrate 12 and a conductive coat or coating 14. Each of the conductive coats 14 of the electrode plates 10A and 10B includes a first conductive member 16 laminated on the substrate 12, and a second conductive member 18 (or dot-like elements 20) placed on the first conductive member 16 in a distributed manner. The substrates 12 and the conductive coats 14 of the electrode plates 10A and 10B have rectangular profiles substantially identical to each other as seen in a plan view.

A pair of strip-shaped, positive and negative first electrodes (i.e., a first parallel electrode pair) 32 is provided on the conductive coat 14 of the first electrode plate 10A at a location along a pair of opposing sides of the rectangular profile, and patterned and laminated directly on the conductive coat 14 by, e.g., a screen printing, so as to be electrically connected to the conductive coat 14. Similarly, a pair of strip-shaped, positive and negative second electrodes (i.e., a second parallel electrode pair) 34 is provided on the conductive coat 14 of the second electrode plate 10B at a location along another pair of opposing sides of the rectangular profile, different from the location of the first parallel electrode pair 32, and patterned and laminated directly on the conductive coat 14 by, e.g., a screen printing, so as to be electrically connected to the conductive coat 14.

The first electrode plate 10A and the second electrode plate 10B are assembled with each other in a relative arrangement such that their respective conductive coats 14 are opposed to and spaced from each other while permitting a conductive contact therebetween, and are fixed to each other in a mutually superposed state by an electrical-insulating adhesive layer (e.g., a double-sided adhesive tape) 36 having a strip-shape (a rectangular frame shape, in the illustrated embodiment) and provided along the outer edges of the mutually opposing conductive coats 14. In this assembly, the conductive coats 14 are disposed at positions where their respective profiles are substantially aligned with each other, and the first and second parallel electrode pairs 32, 34 connected respectively to the conductive coats 14 are disposed at positions different or rotated from each other by 90 degrees.

In the illustrated embodiment, a pair of first conductors 38 individually connected to the first parallel electrode pair 32 and a pair of second conductors 40 individually connected to the second parallel electrode pair 34 are provided on the conductive coat 14 of the first electrode plate 10A and patterned into predetermined profiles on the first conductive coat 14 through, e.g., screen printing, with an electrical insulating layer 42 interposed between the conductors and the conductive coat. In this configuration, in a state where the first and second electrode plates 10A, 10B are assembled with each other in the aforementioned relative arrangement, the second conductors 40 are individually connected to the corresponding second electrodes 34 via an electrical-conductive portion 44 formed as a part of the adhesive layer 36. The first and second conductors 38, 40 are collected at a predetermined location on the first electrode plate 10A, and connected to a connector (e.g., a flexible printed circuit board) 46 constituting an interface with a not-shown control circuit.

The first and second parallel electrode pairs 32, 34, the first and second conductors 38, 40, as well as the insulating layer 42, are formed within a region where the adhesive layer 36 is provided, and constitute an intermediate layer 48 extending in a strip shape (a rectangular frame shape, in the illustrated embodiment) along the outer edges of the first and second electrode plates 10A, 10B. The intermediate layer 48 acts as a spacer defining and ensuring a spacing distance D between the conductive coats 14 of the first and second electrode plates 10A, 10B.

Each of the first and second electrode plates 10A, 10B includes a frame-like inoperative area (i.e., a frame area) 50 defined correspondingly to an area where the intermediate layer 48 is disposed, and a detecting area 52 having a rectangular profile and encircled by the frame area 50, and detects a touch input by an operator in the detecting area 52 as described below. The second conductive member 18 (the dot-like elements 20) of each conductive coat 14 is disposed in an appropriately distributed manner across the detecting area 52. Further, in the detecting area 52, a plurality of electrical-insulating dot spacers 54 are provided in an appropriately dispersed arrangement on the conductive coat 14 of at least one of the electrode plates 10A, 10B (the first electrode plate 10A, in the drawing). The dot spacers 54 act to suppress an unintended concave bending of the respective electrode plate 10A, 10B due to, e.g., their own weight, so as to keep a gap between the opposed conductive coats 14. On the other hand, when either one of the electrode plates 10A, 10B is deformed under pressing force, the dot spacers 54 act to permit a local contact between the opposed conductive coats 14 at a pressing point.

Each of the dot-like elements 20 constituting the second conductive member 18 of the conductive coat 14 of each electrode plate 10A, 10B has a cylindrical shape with a diameter in the range of, e.g., about 5 μm to 100 μm, and the dot-like elements 20 are arranged on the surface 16a of the first conductive member 16 with a pitch in the range of, e.g., about 50 mm to 500 μm. On the other hand, each of the dot spacers 54 has a hemispherical shape with a diameter in the range of, e.g., about 20 μm to 200 μm, and the dot spacers 54 are arranged on the surface 16a of the first conductive member 16 with a pitch in the range of, e.g., about 1 mm to 5 mm. The dot spacers 54 are formed in a regular arrangement, such as a square grid-array, by, e.g., photolithographic technique or screen printing, after the second conductive member 18 is formed on the surface 16a of the first conductive member 16.

The panel-type input device 30 operates, under the control of a control circuit (not illustrated), by applying a predetermined voltage alternately to the first parallel electrode pair 32 and the second parallel electrode pair 34, connected respectively to the conductive coat 14 of the first electrode plate 10A and the conductive coat 14 of the second electrode plate 10B. In this state, at the instant when an operator presses a desired point on the outer surface of, e.g., the substrate 12 of the second electrode plate 10B with a pen, a finger, etc. (i.e., when the operator performs a touch input), the conductive coats 14 come into conductive contact with each other at the pressed point, and a divided voltage corresponding to a resistance value of each conductive coat 14 determined by the position of the pressed point is output from one of the conductive coats 14 to which a voltage is not applied. A processing section (not illustrated) provided in the control circuit detects the occurrence of the touch input due to a signal conducted through the conductive coats 14, measures the divided voltages alternately generated in the conductive coats 14, and thereby detects a two-dimensional coordinate of the pressed point.

In this connection, the aforementioned size and arrangement pitch of the second conductive member 18 (or the dot-like elements 20) are appropriately set so that, when the conductive coats 14 of the electrode plates 10A, 10B come into conductive contact with each other by the touch input, the second conductive member 18 (or the dot-like elements 20) of the first conductive coat 14 comes into contact with the second conductive coat 14 prior to the first conductive member 16 of the first conductive coat 14. Thus, the panel-type input device 30 is configured so that the second conductive member 18 (or the dot-like elements 20) of the conductive coat 14 of each electrode plate 10A, 10B contacts the opposed counterpart conductive coat 14 in principle, regardless of the position of the touch input. In order to achieve this configuration, in the illustrated embodiment, the second conductive members 18 (or the dot-like elements 20) of the electrode plates 10A, 10B are formed so as not to oppositely face each other but to be laterally shifted from each other (FIG. 4). However, the configuration of the second conductive members 18 is not limited to the illustrated arrangement, and the second conductive members 18 (or the dot-like elements 20) of the electrode plates 10A, 10B may oppositely face each other, depending on the size and arrangement pitch of the second conductive members 18 (or the dot-like elements 20).

The panel-type input device 30 may be configured as a touch panel having a transparent structure, which can be mounted to be superposed on a screen of a display unit (not illustrated), such as a liquid crystal display (LCD), a plasma display panel (PDP), a cathode ray tube (CRT), etc. Alternatively, the panel-type input device 30 may be configured as an opaque or translucent structure known as a pointing device. The panel-type input device 30 configured as a transparent touch panel may have an exemplary configuration such that the first electrode plate 10A is used as a lower-side electrode plate disposed adjacent to the screen of a display unit and the substrate thereof is formed from a transparent glass or resin plate or a transparent resin film, and that the second electrode plate 10B is used as an upper-side electrode plate subjected to a pressing operation by an operator and the substrate 12 thereof is formed from a transparent resin film with high flexibility.

As previously explained, the panel-type input device 30 according to the illustrated embodiment has a configuration wherein the conductive coat 14 of each electrode plate 10A, 10B includes the first conductive member 16 made of a conducting polymer and laminated on the surface 12a of the substrate 12 and the second conductive member 18 made of an inorganic conductive material and placed on the surface 16a of the first conductive member 16 in a distributed manner, and wherein the second conductive member 18 (or the dot-like elements 20) of the conductive coat 14 of each electrode plate 10A, 10B comes into conductive contact with the opposed counterpart conductive coat 14 upon the touch input operation. Consequently, even if an instantaneous relatively large current (hereinafter referred to as an inrush current) flows through the contact point between the conductive coats 14 depending on a voltage applied to the opposed conductive coats 14 insulated from each other at the moment when the conductive coats 14 come into contact with each other by the touch input operation, the inrush current first flows through the second conductive member 18 having the electric conductivity higher than that of the first conductive member 16, and as a result, it is possible to prevent the conductive coats 14 from causing a structural deterioration and increase in electrical resistance due to the inrush current. Typically, a conductive coat or coating tends to be more likely to be damaged by an inrush current as the electrical conductivity thereof decreases. Contrary to this, in the panel-type input device 30, according to the characteristic configuration of the electrode plates 10A, 10B described above, it is possible to prevent the local increase in resistance of the conductive coats 14 due to the repeated touch input operation at the same point, and consequently, it is possible to prevent malfunctions such that errors occur in a coordinate detection position and a touch input cannot be detected.

Further, as previously explained, the conductive coat 14 of each electrode plate 10A, 10B exhibits excellent mechanical strength due to the cooperation of the first conductive member 16 and the second conductive member 18, and the entire electric conductivity of the conductive coat 14 is substantially not affected even if the upper second conductive member 18 is mechanically damaged so that the conductive coat 14 has also excellent electrical durability. Therefore, it is possible to improve safety and reliability of the panel-type input device 30 in which the conductive coats frequently make contact with or detach from each other. Moreover, as previously explained, when the panel-type input device 30 is configured as a transparent touch panel, it is possible to reduce an influence on a screen visibility (i.e., to prevent degradation in transmittance) of a display unit through the electrode plates 10A and 10B, according to the distributed arrangement of the second conductive member 18, and it becomes possible to form the second conductive member 18 from an opaque inorganic conductive material such as carbon, which gives an advantage in more choices in materials.

In the panel-type input device 30 according to the illustrated embodiment, each of the pair of electrode plates 10A and 10B is provided with the conductive coat 14 including the first conductive member 16 and the second conductive member 18. Alternatively, as illustrated in FIG. 5, a modified panel-type input device may be configured so that only one of electrode plates (electrode plate 10B, in the drawing) is provided with a conductive coat or coating 14 including a first conductive member 16 and a second conductive member 18 and the other electrode plate 10′ is provided with a single-layered conductive coat or coating 14′. In this configuration, the conductive coat 14′ of the electrode plate 10′ may be formed by using a conducting polymer similar to the first conductive member 16, or using an inorganic conductive material similar to the second conductive member 18. The panel-type input device of the illustrated modification also exhibits an effect similar to that of the aforementioned panel-type input device 30.

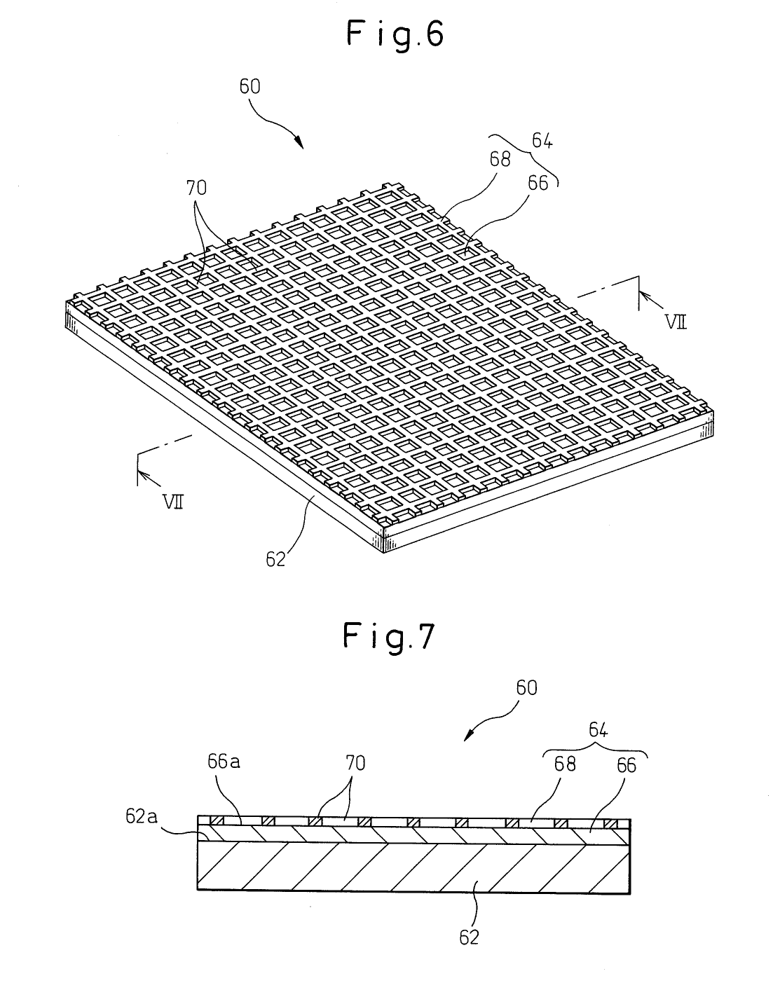

FIGS. 6 and 7 illustrate an electrode plate 60 with a conductive coat, according to a second embodiment of the present invention. The electrode plate 60 includes an electrically insulating substrate 62, and an electrically conductive coat or coating 64 provided on a surface 62a of the substrate 62. The substrate 62 may have a configuration (materials, dimensions, etc.) similar to that of the substrate 12 of the aforementioned electrode plate 10.

The conductive coat 64 includes a first conductive member 66 laminated on the surface 62a of the substrate 62, and a second conductive member 68 placed on a surface 66a of the first conductive member 66 in a distributed manner. The first conductive member 66 is formed by using an electrically conductive polymer (i.e., a conducting polymer) so as to entirely cover the surface 62a of the substrate 62 as a coating. The second conductive member 68 is formed by using an inorganic conductive material so as to be appropriately distributed across the entire surface 66a of the first conductive member 66 as a member separated from the first conductive member 66. In the illustrated embodiment, the second conductive member 68 includes a plurality of linear elements 70 joined to each other in a net-like manner. The linear elements 70 are arranged across the entire surface 66a of the first conductive member 66 in a uniformly distributed manner. When the electrode plate 60 is used to constitute a resistive-type touch panel, the first conductive member 66 is formed from a transparent material. The first conductive member 66 may have a configuration (materials, dimensions, etc.) similar to that of the first conductive member 16 of the aforementioned electrode plate 10.

As the inorganic conductive material of the second conductive member 68, materials similar to those of the second conductive member 18 of the aforementioned electrode plate 10 may also be selected. Further, thickness of the second conductive member 68 may be set in the range similar to that of the second conductive member 18. Each of the linear elements 70 constituting the second conductive member 68 has a rib shape with a width in the range of, e.g., about 5 μm to 50 μm. The linear elements 70 are arranged on the surface 66a of the first conductive member 66 with a line-to-line pitch in the range of, e.g., about 50 μm to 1 mm. In the illustrated embodiment, the linear elements 70 constituting the second conductive member 68 extend in the directions of orthogonal two axes, and are formed entirely in a regular square-grid arrangement on the surface 66a of the first conductive member 66, but may be formed entirely or partially in an irregular arrangement. Process for forming the second conductive member 68 made of the inorganic conductive material may be similar to the process for forming the second conductive member 18 of the aforementioned electrode plate 10.

In the electrode panel 60 configured as described above, similarly to the aforementioned electrode plate 10, the mechanical strength and electrical durability of the conductive coat 64 is improved due to the cooperation of the first conductive member 66 and the second conductive member 68. Further, in the electrode plate 60, the second conductive member 68 is formed on the first conductive member 66 in a distributed manner, and therefore, similarly to the aforementioned electrode plate 10, it is possible to prevent degradation in transmittance of the electrode plate 60, and there is an advantage in more choices in materials of the second conductive member 68. Thus, the electrode plate 60 can be safely and preferably used as an electrode plate of a resistive-type, panel-type input device in which opposing conductive coats frequently contact with or detach from each other.

While the invention has been described with reference to specific preferred embodiments, it will be understood by those skilled in the art that various changes and modifications may be made thereto without departing from the scope of the following claims.

1. An electrode plate with a conductive coat, comprising:
a substrate; and
a conductive coat provided on a surface of said substrate,
said conductive coat comprising:
a first conductive member laminated on said surface of said substrate, said first conductive member being formed from a conducting polymer; and
a second conductive member placed on a surface of said first conductive member in a distributed manner, said second conductive member being formed from an inorganic conductive material,
wherein an electric conductivity of said inorganic conductive material forming said second conductive member is higher than an electric conductivity of said conducting polymer forming said first conductive member.

2. An electrode plate with a conductive coat according to claim 1, wherein said second conductive member includes a plurality of dot-like elements separated from each other.

3. An electrode plate with a conductive coat according to claim 1, wherein said second conductive member includes a plurality of linear elements joined to each other in a net-like manner.

4. An electrode plate with a conductive coat according to claim 1, wherein said substrate and said first conductive member are transparent.

5. A panel-type input device comprising:
a pair of electrode plates, each electrode plate comprising a substrate and a conductive coat provided on a surface of said substrate, said pair of electrode plates being assembled with each other in a relative arrangement such that conductive coats of said electrode plates are opposed to and spaced from each other while permitting a conductive contact between said conductive coats,
wherein at least one of said pair of electrode plates comprises the electrode plate of claim 1.

6. A panel-type input device according to claim 5, wherein each of said pair of electrode plates comprises a detecting area adapted to detect a touch input, and wherein said second conductive member is disposed in said detecting area in a distributed manner and a plurality of dot spacers made of an electrically insulating material are provided in said detecting area in a dispersed arrangement.
